(19) United States
(12) Patent Application Publication
(10) Pub. No.: US 2019/0048459 A1
(43) Pub. Date: Feb. 14, 2019

(54) EVAPORATION SOURCE DEVICE FOR EVAPORATING

(71) Applicant: WUHAN CHINA STAR OPTOELECTRONICS TECHNOLOGY CO., LTD., Wuhan, Hubei (CN)

(72) Inventor: Wei Yu, Wuhan (CN)

(21) Appl. No.: 15/570,668

(22) PCT Filed: Jul. 12, 2017
(86) PCT No.: PCT/CN2017/092663

§ 371 Date: Oct. 30, 2017

(30) Foreign Application Priority Data
Jun. 28, 2017 (CN) 201710505480.0

(51) Int. Cl. C23C 14/24; C23C 14/54; C23C 14/12; H01L 51/00; H01L 51/56

(52) U.S. Cl. CPC C23C 14/243; C23C 14/545; H01L 51/56; H01L 51/001; C23C 14/12

(57) ABSTRACT

The present disclosure discloses an evaporation source device for evaporating including a heating container having an opening on a top surface thereof and first and second baffles disposed on the opening of the heating container and having through holes disposed thereon, respectively, wherein the first and second baffles are relatively slidable so that the through holes of the first and second baffles fit at at least two different fitting positions to form an evaporating passage that communicates with the heating container. The first baffle and the second baffle are disposed at the opening of the heating container, the first baffle may fit with the second baffle by movement of the first baffle and the second baffle to form different evaporation passages, and the evaporation passages may be replaced without opening a vacuum chamber, which solves a problem that the organic electroluminescent material blocks the hole in the evaporating process well.

### TECHNICAL FIELD

The present disclosure relates to a technical field of an organic electroluminescent device, and particularly relates to an evaporation source device for evaporating.

### BACKGROUND ART

An OLED (i.e., organic electroluminescent device) display is a new generation of display, in which an organic thin film is disposed on an OLED substrate and sandwiched between cathode and anode electrodes or a conductive layer, and emits light after applying a voltage to the two electrodes. Compared to a liquid crystal display, the OLED display has various advantages such as self-luminous, fast response, wide viewing angle, full color and the like, and thus industrialization of the OLED display is rapidly developed in recent years.

At present, a main method of manufacturing the OLED display is vacuum thermal evaporation in which an OLED organic material is heated by using a crucible in a vacuum chamber. The existing crucible for heating the OLED material comprises a crucible body and a crucible lid covered at an opening end of the crucible body, and evaporation holes are provided on the crucible lid. The crucible body is used to contain the OLED organic material so that the OLED material is heated to sublimate or evaporate at a certain temperature and then is deposited on the substrate through the evaporation holes there above, thereby forming an organic thin film.

During evaporation of the OLED material, organic substance evaporated, due to its fluffy structure, easily aggregates at the evaporation holes of the crucible lid until the evaporation holes are completely blocked. However, due to the specialty of fabrication process of the OLED display, the fabrication of OLED display needs to be carried out in a continuous vacuum environment until the evaporation of the organic material is continuously finished. Once the evaporation holes are blocked, the evaporation could not continue to be performed, which causes the evaporation process cannot proceed, and seriously affects a production schedule.

In this case, under the current practice, the OLED material has to be firstly cooled to a room temperature, and subsequently the evaporation chamber is opened to clean the blocked holes of the evaporation source, and then is closed, followed by re-vacuuming and heating to a certain temperature to continue the evaporation process. This usually takes tens of hours, and opening the chamber can easily lead to dust entering into the chamber, thereby seriously affecting yield and product quality.

### SUMMARY

In view of the above deficiencies existing in the prior art, the present disclosure provides an evaporation source device for evaporating which can solve the problem that the evaporation holes of evaporating the crucible are blocked without opening the vacuum chamber.

In order to achieve the above purpose, the present disclosure adopts the following technical solutions.

An evaporation source device for evaporating includes a heating container having an opening on a top surface thereof and, first and second baffles disposed on the opening of the heating container, and having through holes disposed thereon, respectively. The first and second baffles are relatively slidable so that the through holes of the first and second baffles mate at at least two different fitting positions to form an evaporating passage that communicates with the heating container.

As one implementation, the first baffle and the second baffle are layered in the height direction of the heating container and extend in directions cross, the through holes on the first baffle and the second baffle each are bar-shaped holes extending in the longitudinal direction of the corresponding baffle, and the first baffle and the second baffle each are movable along the respective longitudinal directions so that the through holes disposed up and down communicate in the height direction of the heating container to form different evaporation passages.

As one implementation, the through hole on the first baffle is a bar-shaped hole extending in the longitudinal direction thereof, the through hole on the second baffle is dot-like through holes spaced apart in the longitudinal direction thereof.

Alternatively, the through holes on the first baffle and the second baffle are dot-like through-holes disposed to be spaced apart in the longitudinal directions of respective baffles.

Or, the through holes on the first baffle and the second baffle each are bar-shaped through-holes extending along the longitudinal directions of respective baffles.

As one embodiment, the first baffle and the second baffle perpendicular to each other.

As one embodiment, the heating container is a crucible.

Or, the first baffle and the second baffle are provided adjacent in the radial direction of the heating container; and the first baffle has a plurality of first notches disposed thereon to be spaced apart, and the second baffle has a plurality of second notches disposed thereon to be spaced apart, and the second baffle is movable in its longitudinal direction relative to the first baffle so that different first notches fit with the second notches to form different evaporation passages.

Conical shape semi-cover portions enclosed as throat-like are correspondingly provided on the first baffle and the second baffle around the first notch and the second notch, respectively, and the semi-cover portion around the first notch and the semi-cover portion around the second notch is the same in size.

Or, the second baffle is provided on the upper surface of the first baffle, an inclined throat-like cover portion is provided beside the through hole of the second baffle, and the cover portion has an end with a size smaller than a size of the through hole of the second baffle.

According to the present disclosure, the first baffle and the second baffle are disposed at the opening of the heating container containing the organic electroluminescent material, the first baffle may fit with the second baffle by the movement of the first baffle and the second baffle to form different evaporation passages, and the evaporation passages may be replaced without opening the vacuum chamber, which solves a problem that the organic electroluminescent material blocks the hole in the evaporating process well, and improves production yield and product quality.

### DESCRIPTION OF DRAWINGS

FIG. 1 is a structure schematic diagram of an evaporation source device according to Embodiment 1 of the present disclosure;

FIG. 2 is a schematic diagram of a first usage state of an evaporation source device according to Embodiment 1 of the present disclosure;

FIG. 3 is a schematic diagram of a second usage state of an evaporation source device according to Embodiment 1 of the present disclosure;

FIG. 4 is a partial structure schematic diagram of an evaporation source device according to Embodiment 1 of the present disclosure;

FIG. 5 is a schematic diagram of a usage state of an evaporation source device according to Embodiment 2 of the present disclosure;

FIG. 6 is a schematic diagram of a first usage state of an evaporation source device according to Embodiment 3 of the present disclosure;

FIG. 7 is a schematic diagram of a second usage state of an evaporation source device according to Embodiment 3 of the present disclosure; and

FIG. 8 is a partial structure schematic diagram of an evaporation source device of Embodiment 3 of the present disclosure.

### DETAILED DESCRIPTION

In order to make a purpose, technical solutions and advantages of the present disclosure to be clearer and understood, the present disclosure will be further explained below in conjunction with the attached drawings and embodiments. It should be understood that, the described specific embodiments here are only used to explain the present disclosure, but not used to limit the present disclosure.

An evaporating source device of the present disclosure is mainly used for heating and evaporating an OLED organic material to form an organic thin film, and is placed in a vacuum chamber when being used. and the evaporating source device includes a heating container having an opening on a top surface thereof, and first and second baffles disposed on the opening of the heating container, on which through holes are disposed, respectively. The first and second baffles are relatively slidable so that the through holes on the first and second baffles fit at at least two different fitting positions to form an evaporating passage that communicates with the heating container.

Here, the opening of the heating container is described as a reference, and the evaporation passage formed by the first and second baffles is right above the opening of the heating container, and the first and second baffles shield the opening of the heating container, leaving only the deposition passage as a deposition passage for an organic material. In an initial state, the through hole of the first baffle and the through hole of the second baffle communicate at a first fitting position to form a first evaporating passage having a through-hole structure, and during evaporating, the organic material aggregates at a portion where the evaporating passage is formed, until the evaporating passage is blocked; and then, the first baffle plate and the second baffle plate move relatively so as to stagger by a certain distance, and a second fitting position different from the first fitting position is communicated to form a second evaporation passage having a through-hole structure, and as such, the evaporation passage may be replaced without opening the vacuum chamber, thereby improving the evaporation efficiency and avoiding dust, etc. from entering. Hereinafter, a general concept of the present disclosure is described more particularly with several different ways of forming the evaporation passages.

### Embodiment 1

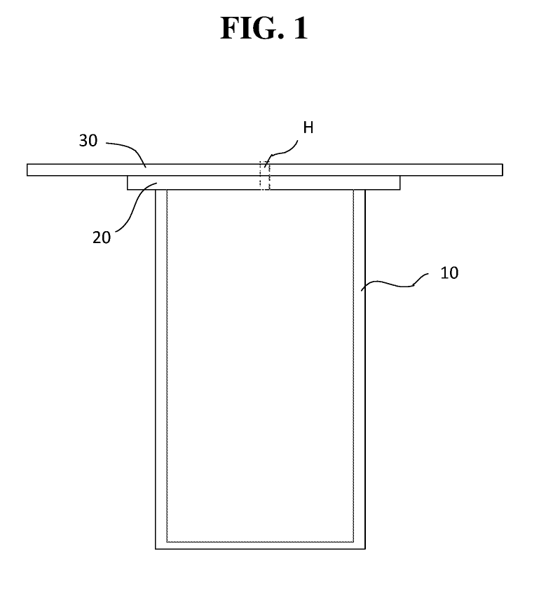

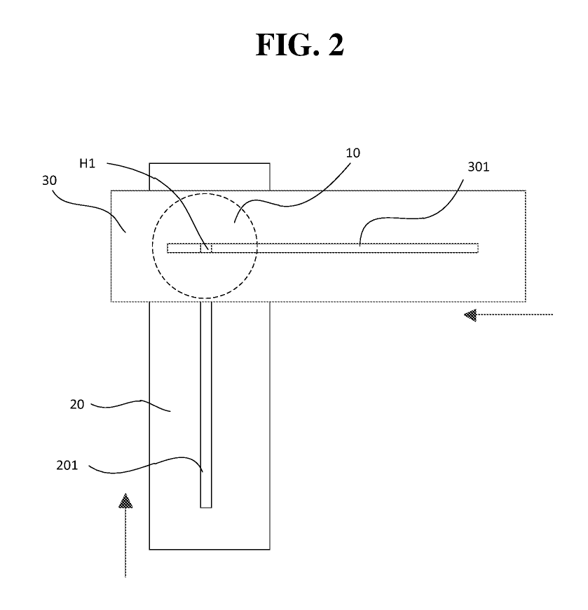

Referring to FIGS. 1 and 2, an evaporation source device of the present embodiment includes a heating container 10 having an opening on a top surface thereof, and first and second baffles 20 and 30 disposed on the opening of the heating container 10. The heating container 10 is preferably a crucible, and the first baffle 20 and the second baffle 30 are laminated in a height direction of the heating container 10 (a vertical direction as shown in FIG. 1) and are disposed to cross in extending directions thereof. The through holes on the first baffle 20 and the second baffle 30 each are bar-shaped holes extending in longitudinal directions of respective baffles, that is, the first baffle 20 has a first bar-shaped hole 201 provided thereon, and the second baffle 30 has a second bar-shaped hole 301 provided thereon.

After being mounted to the opening on the top surface of the heating container 10, the first baffle 20 and the second baffle 30 each are movable along respective longitudinal directions so that the first bar-shaped hole 201 and the second bar-shaped hole 301 disposed up and down communicate in sequence in the vertical direction to form a different evaporation passage H, wherein the first baffle 20 and the second baffle 30 in the embodiment are perpendicular to each other so as to more easily control the direction of movement and displacement of the first baffle 20 and the second baffle 30.

It may be understood that driving mechanisms for driving translation of the first baffle 20 and the second baffle 30 may be a variety of possible driving mechanisms in the prior art, for example, continuous evaporation can be achieved by mounting the driving mechanisms within the vacuum chamber with a pinion and rack drive, a belt drive, a hydraulic rod drive, a linkage mechanism drive, etc. The first bar-shaped hole 201 and the second bar-shaped hole 301 in the present embodiment are both regular rectangular holes, and as an improvement, in other embodiments, the first bar-shaped hole 201 and the second bar-shaped hole 301 may be irregular bar-shaped holes, that is, the bar-shaped holes have widths not always consistent in their longitudinal direction and may have different widths so that the width of the evaporation passage H is changed by changing the passage fitting position of the first bar-shaped hole 201 and the second bar-shaped hole 301.

The first baffle 20 and the second baffle 30 translates in directions perpendicular to each other, the first bar-shaped hole 201 and the second bar-shaped hole 301 have an overlapping area projected in the vertical direction, which is the area corresponding to the evaporation passage formed by actual fitting, and as relative movements of the first baffle 20 and the second baffle 30, different regions the first bar-shaped hole 201 and different regions of the second bar-shaped hole 301 may be combined to form a plurality of evaporation passages H, which may make it convenient to replace some evaporation passage after they are blocked.

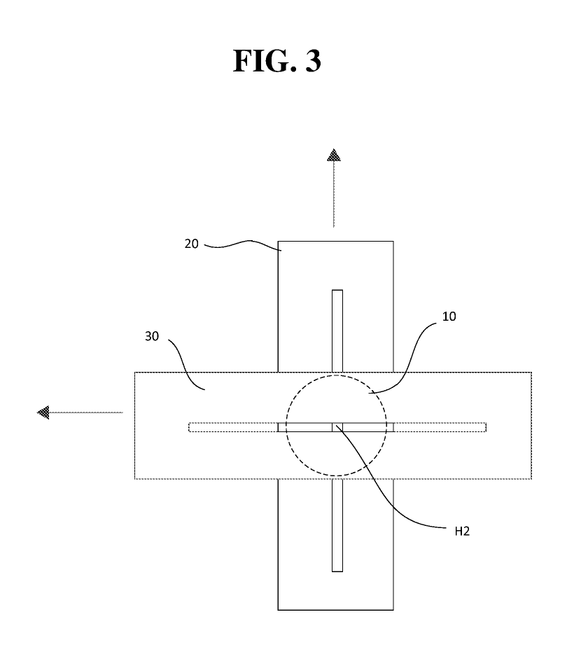

Specially, an shown in FIGS. 2 and 3, in an initial operation, the first baffle 20 and the second baffle 30 are stationary and perpendicularly intersecting, and first end of the first bar-shaped hole 201 and the second bar-shaped holes 301 are both positioned at an origin position, the first baffle 20, the second baffle 30, and the heating container 10 constituting a heating chamber for placing an organic material and a evaporation passage H at a top of the heating chamber, wherein the first ends of the first bar-shaped hole 201 and the second bar-shaped holes 301 are fitted to form a first evaporation passage H1. The organic material is concentrated at the evaporation passage H1 where the organic material is formed as the vapor deposition process proceeds. After the evaporation passage H1 is blocked, the first baffle 20 and the second baffle 30 are pushed along respective longitudinal directions (arrow directions as shown in FIGS. 2 and 3), respectively, so that the first bar-shaped hole 201 and the second bar-shaped holes 301 perpendicular to each other may fit each other to form a new second evaporation passage H2, and as such, the evaporation process may be continued through the second evaporation passage H2 until the new second deposition passage H2 is blocked, and the first baffle 20 and the second baffle 30 are moved to form a new evaporation passage. When the first bar-shaped hole 201 and the second bar-shaped hole 301 are fully blocked, it is necessary to open the vacuum chamber to clean up.

Further, the heating container 10 in the present embodiment may be further modified to have a dial needle (not shown) erected and fixed at its opening, and when the first baffle 20 and the second baffle 30 are mounted in the heating container 10, the dial needle is simultaneously inserted into the first bar-shaped hole 201 and the second bar-shaped hole 301, and during the movement of the first baffle 20 and the second baffle 30, the dial needle is always within the first bar-shaped hole 201 and the second bar-shaped hole 301 at the same time. When the first bar-shaped hole 201 and the second bar-shaped hole 301 are partially blocked, the first baffle 20 and the second baffle 30 can be controlled by the drive mechanism, the organic material blocked in the first bar-shaped hole 201 and the second bar-shaped hole 301 is removed by using the dial needle, and as such, the infinite-time and uninterrupted evaporation may be achieved.

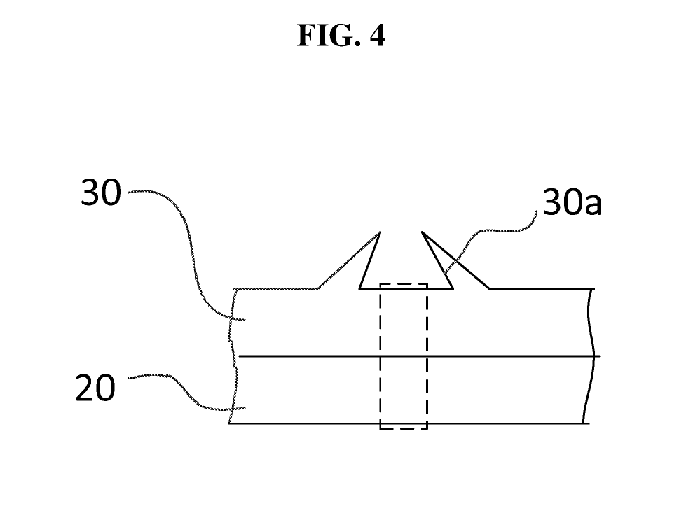

Furthermore, as shown in FIG. 4, the second baffle 30 is provided on an upper surface of the first baffle 20, and a throat-like cover portion 30a is provided beside the through hole of the second baffle 30. The cover portion 30a has a size smaller than the size of the through hole of the second baffle 30, the ejection force of the organic material discharged through the evaporation passage H can be increased, and the inclined throat-like configuration may also relieve a phenomenon that the organic material falling from the substrate above fall around the second bar-shaped hole 301 and cause the evaporation passage blocked at the same time.

### Embodiment 2

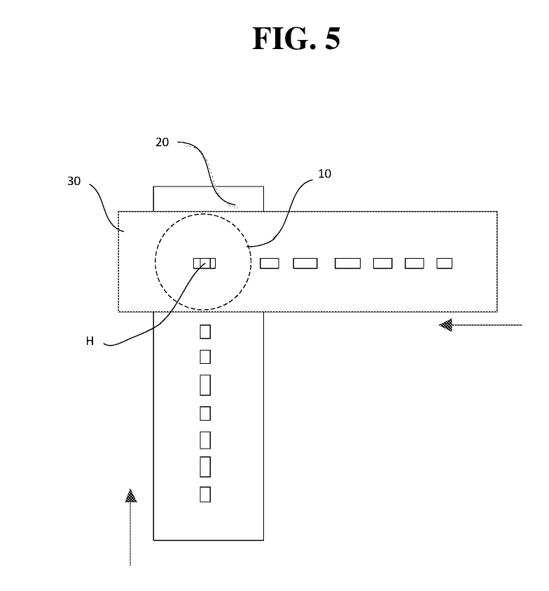

As shown in FIG. 5, unlike Embodiment 1, through holes on a first baffle 20 and a second baffle 30 of the present embodiment are dot-like through holes disposed to be spaced apart in longitudinal directions of respective baffles, and are not a whole bar-shaped hole.

During movement of the first baffle 20 and the second baffle 30, the dot-like through holes of the first baffle 20 may fit with the corresponding dot-like through holes of the second baffle 30 above thereof to form an evaporation passage H, and when one of the dot-like through holes in the first baffle 20 or the second baffle 30 is blocked, the dot-like through-hole may be replaced by moving the baffle where the blocked dot-like through-hole is to form a new evaporation passage H.

It may be understood that, in other embodiments, the through holes on the first baffle 20 may be bar-shaped holes extending in the longitudinal direction thereof, and the through holes on the second baffle 30 may be dot-like through holes disposed to be spaced apart in the longitudinal direction thereof. During the movement of the first baffle 20 and the second baffle 30, different portions of the bar-shaped hole of the first baffle 20 mate with different dot-like through holes on the second baffle 30 to form different evaporation passage H.

### Embodiment 3

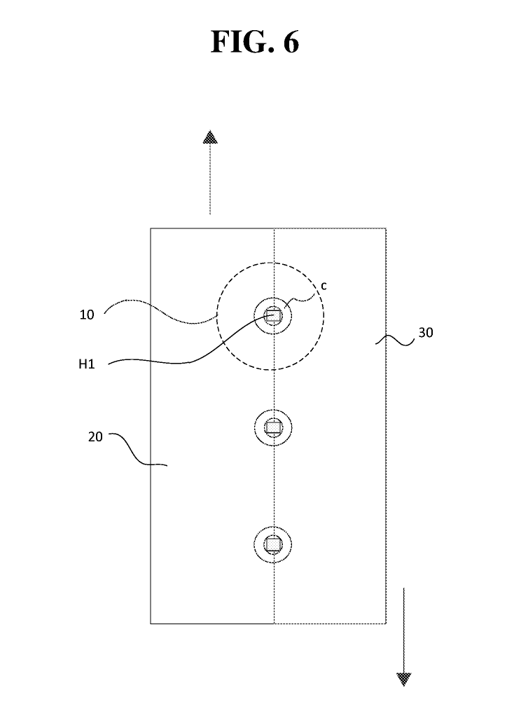

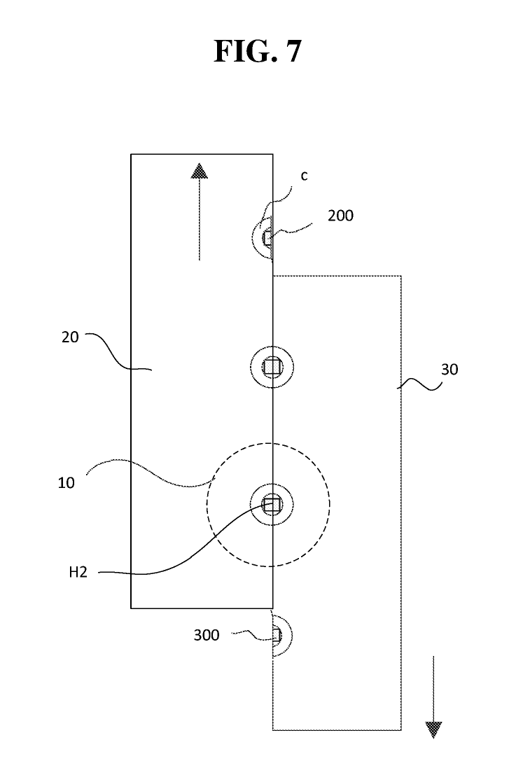

As shown in FIGS. 6 and 7, unlike Embodiment 1 and Embodiment 2, a first baffle 20 and a second baffle 30 of the present embodiment are provided adjacent in a radial direction of a heating container 10 (i.e., the horizontal direction of FIG. 1), and the first baffle 20 and the second baffle 30 are arranged in a spliced manner to form a evaporation passage. Specifically, the first baffle 20 is provided with first notches 200 disposed thereon spaced apart in plural, and the second baffle 30 is provided with second notches 300 disposed thereon spaced apart in plural, and the second baffle 30 may move in its longitudinal direction relative to the first baffle 20 so that different first notches 200 fit with the second notches 300 to form different evaporation passages.

As in FIG. 6, in an initial operation, the first notches 200 at an edge of the first baffle 20 correspond to the second notches 300 at an edge of the second baffle 30 one to one, each of the first notches 200 is spliced with one second notch 300 to form a rectangular through hole, wherein the through hole formed by a pair of notches is an initial first evaporation passage H1. After the first evaporation passage H1 is blocked, the first baffle 20 and the second baffle 30 move in a contrary direction so that the first notch 200 staggers with the second notch 300, and once a new through hole is formed by the first notch 200 and the second notch 300 above the opening of the heating container 10, the movement is stopped, and the new through hole become a new second evaporation passage H2 (as in FIG. 7), and thus the evaporating may continue.

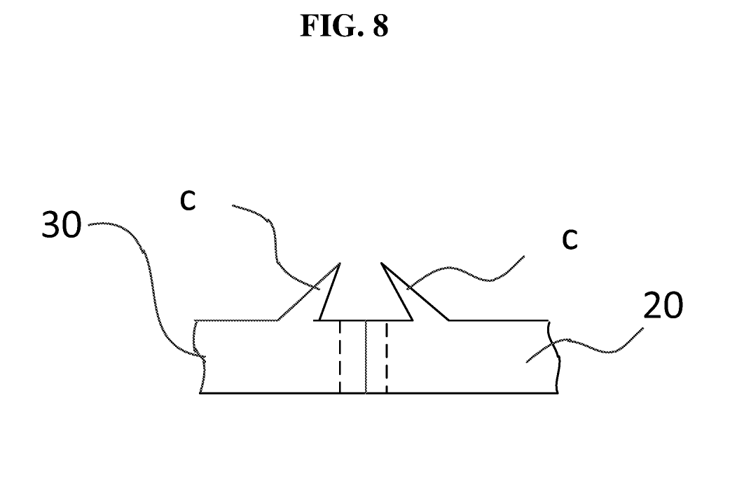

In addition, as shown in connection with FIG. 8, a conical shape semi-cover portions c enclosed as throat-like are correspondingly provided on the first baffle 20 and the second baffle 30 of the present embodiment around the first notch 200 and the second notch 300, respectively, and the semi-cover portion c around the first notch 200 and the semi-cover portion c around the second notch 300 is the same in size. After the evaporation passage is formed, the left and right semi-cover portions c may enclose a complete covering portion, the inclined throat-like configuration may also relieve a phenomenon that the organic material falling from the substrate above falls around the evaporation passage and cause the evaporation passage blocked.

It may be understood that only one of the first baffle 20 and the second baffle 30 in the present embodiment may slide relative to the heating container 10 so that the first baffle 20 fits with the second baffle 30 at at least two fitting position to form the evaporation passage communicating with the heating container 10.

The first notch 200 and the second notch 300 stagger with each other due to the relative movement of the first baffle 20 and the second baffle 30, and when one of the evaporation passage is blocked, the movement of the first baffle 20 and the second baffle 30 may make the organic material in the blocked evaporation passage cracked so that the evaporation passage resume the smooth state and may be reused.

According to the present disclosure, the first baffle and the second baffle are disposed at the opening of the heating container filled with the organic electroluminescent material, and the first baffle may fit with the second baffle by the movement of the first baffle and the second baffle to form the evaporation passage, and the evaporation passage may be replaced without opening the vacuum chamber, which solves a problem that the organic electroluminescent material blocks the hole in the evaporating process, and improves production yield and product quality.

The above descriptions are only detailed description of the present application, and it should be pointed out that, to those ordinary skilled in the art, several improvements and modifications can be made without departing from the principle of the present application, and also those improvements and modifications should be considered as the protection scope of the present application.

What is claimed is:

1. An evaporation source device for evaporating, comprising:
a heating container having an opening on a top surface thereof; and
a first baffle and a second baffle disposed on the opening of the heating container, and having through holes disposed thereon, respectively,
wherein the first and second baffles are relatively slidable so that the through holes of the first and second baffles fit at at least two different fitting positions to form an evaporating passage that communicates with the heating container.

2. The evaporation source device for evaporating of claim 1, wherein the second baffle is provided on an upper surface of the first baffle, an inclined throat-like cover portion is provided beside the through hole of the second baffle, and the cover portion has an end with a size smaller than a size of the through hole of the second baffle.

3. The evaporation source device for evaporating of claim 1, wherein the first baffle and the second baffle are laminated in a height direction of the heating container and are disposed to cross in extending directions thereof, the through holes on at least one of the first and second baffle are bar-shaped holes extending in a longitudinal direction of the at least one of the first and second baffles, and the first baffle and the second baffle are movable along respective longitudinal directions so that the through holes disposed up and down communicate in the height direction of the heating container to form different evaporation passages.

4. The evaporation source device for evaporating of claim 3, wherein the second baffle is provided on an upper surface of the first baffle, an inclined throat-like cover portion is provided beside the through hole of the second baffle, and the cover portion has an end with a size smaller than a size of the through hole of the second baffle.

5. The evaporation source device for evaporating of claim 3, wherein the through hole on the first baffle is a bar-shaped hole extending in the longitudinal direction thereof, the through hole on the second baffle is dot-like through holes spaced apart in the longitudinal direction thereof.

6. The evaporation source device for evaporating of claim 5, wherein the second baffle is provided on an upper surface of the first baffle, an inclined throat-like cover portion is provided beside the through hole of the second baffle, and the cover portion has an end with a size smaller than a size of the through hole of the second baffle.

7. The evaporation source device for evaporating of claim 3, wherein the through holes on the first baffle and the second baffle are dot-like through-holes disposed to be spaced apart in the longitudinal directions of respective baffles.

8. The evaporation source device for evaporating of claim 7, wherein the second baffle is provided on an upper surface of the first baffle, an inclined throat-like cover portion is provided beside the through hole of the second baffle, and the cover portion has an end with a size smaller than a size of the through hole of the second baffle.

9. The evaporation source device for evaporating of claim 3, wherein the through holes on the first baffle and the second baffle are bar-shaped through-holes extending along the longitudinal directions of respective baffles.

10. The evaporation source device for evaporating of claim 9, wherein the second baffle is provided on an upper surface of the first baffle, an inclined throat-like cover portion is provided beside the through hole of the second baffle, and the cover portion has an end with a size smaller than a size of the through hole of the second baffle.

11. The evaporation source device for evaporating of claim 9, wherein the first baffle and the second baffle are perpendicular to each other.

12. The evaporation source device for evaporating of claim 11, wherein, the second baffle is provided on an upper surface of the first baffle, an inclined throat-like cover portion is provided beside the through hole of the second baffle, and the cover portion has an end with a size smaller than a size of the through hole of the second baffle.

13. The evaporation source device for evaporating of claim 1, wherein the heating container is a crucible.

14. The evaporation source device for evaporating of claim 1, wherein the first baffle and the second baffle are provided adjacent in a radial direction of the heating container; and the first baffle has a plurality of first notches disposed thereon to be spaced apart, and the second baffle has a plurality of second notches disposed thereon to be spaced apart, and the second baffle is movable in its longitudinal direction relative to the first baffle so that different first notches fit with the second notches to form different evaporation passages.

15. The evaporation source device for evaporating of claim 14, wherein the second baffle is provided on an upper surface of the first baffle, an inclined throat-like cover portion is provided beside the through hole of the second baffle, and the cover portion has an end with a size smaller than a size of the through hole of the second baffle.

16. An evaporation source device for evaporating, comprising:
a heating container having an opening on a top surface thereof; and
a first baffle and a second baffle disposed on the opening of the heating container, and having through holes disposed thereon, respectively,
wherein the first and second baffles are relatively slidable so that the through holes of the first and second baffles fit at at least two different fitting positions to form an evaporating passage that communicates with the heating container, and
the first baffle and the second baffle are laminated in a height direction of the heating container and extend in directions vertical to each other, the through holes on the first baffle and the second baffle are bar-shaped holes extending in longitudinal directions of respective baffles, and the first baffle and the second baffle each are movable along respective longitudinal directions.
